(19) United States
(12) Patent Application Publication
(10) Pub. No.: US 2020/0017763 A1
(43) Pub. Date: Jan. 16, 2020

(54) OPTICAL MEDIUM AND AN OPTICAL DEVICE

(71) Applicant: Merck Patent GmbH, Darmstadt (DE)

(72) Inventors: Christian MATUSCHEK, Frankfurt Am Main (DE); Arjan MEIJER, Reinheim (DE); Itai LIEBERMAN, Dreieich (DE); Ralf GROTTENMUELLER, Wiesbaden (DE)

(73) Assignee: Merck Patent GmbH, Darmstadt (DE)

(21) Appl. No.: 16/471,166

(22) PCT Filed: Dec. 18, 2017
(86) PCT No.: PCT/EP2017/083247

§ 371 Date: Jun. 19, 2019

(30) Foreign Application Priority Data
Dec. 20, 2016 (EP) 16205342.5

(51) Int. Cl. C09K 11/02; H01L 33/50; C07F 7/10

(52) U.S. Cl. CPC C09K 11/02; B82Y 20/00; C07F 7/10; H01L 33/502

(57) ABSTRACT

The present invention relates to an optical medium (100) and an optical device (200) comprising an optical medium (100). The present invention further relates to a use of the optical medium (100) in an optical device (200). The invention further more relates to method for preparing the optical medium (100) and method for preparing the optical device (200).

### FIELD OF THE INVENTION

The present invention relates to an optical medium (100) and an optical device (200) comprising the optical medium (100). The present invention further relates to a use of the optical medium (100) in an optical device (200). The invention further more relates to method for preparation of the optical medium (100) and method for preparation of the optical device (200).

### BACKGROUND ART

An optical medium including a nanosized fluorescent material and optical devices comprising a light conversion sheet are used in a variety of optical applications, especially for optical devices.

For example, as described in US2014/0264196 A1, WO2014/093391 A2, WO2014/208356 A1, WO2014/196319 A1, and WO 2012/132239 A1.

### PATENT LITERATURE

1. US2014/0264196 A1
2. WO2014/093391 A2
3. WO2014/208356 A1
4. WO2014/196319 A1
5. WO 2012/132239 A1

### SUMMARY OF THE INVENTION

However, the inventors newly have found that there is still one or more of considerable problems for which improvement is desired, as listed below.
1. A novel optical medium comprising a nanosized fluorescent material such as quantum sized materials, and a matrix material, which can show improved initial absolute quantum yield, is desired.
2. A novel optical medium comprising a nanosized fluorescent material, and a matrix material, which can keep good absolute quantum yield, especially in a thermal stress environment, is required.
3. A novel optical medium comprising a nanosized fluorescent material, and a matrix material which can show improved absolute quantum yield in a high humidity environment, is desired.
4. A novel optical medium comprising a nanosized fluorescent material and a matrix material, which can show improved light stress resistivity under light illumination condition.
5. A novel optical medium comprising a nanosized fluorescent material such as quantum sized materials, and a matrix material, which can fit to wet fabrication process well.

The inventors aimed to solve one or more of the aforementioned problems 1 to 5. Surprisingly, the inventors have found a novel optical medium (100) comprising, essentially consisting of, or consisting of at least a light luminescent part (130) and a barrier layer (140) placed over the light luminescent part (130), wherein the light luminescent part (130) comprises at least one nanosized fluorescent material (110), and a matrix material (120) comprising an organo-polysilazane.

In another aspect, the invention relates to use of the optical medium (100) in an optical device.

In another aspect, the invention further relates to an optical device (200) comprising the optical medium (100).

In another aspect, the present invention furthermore relates to method for preparing the optical medium (100) wherein the method comprises at least following steps (a) and (d) in this sequence;

(a) providing at least one nanosized fluorescent material (110), and a organo-polysilazane as a matrix material (120) onto a substrate,
(b) applying steam process at a temperature in the range from 35° C. to 180° C.
(c) preparing a barrier layer (140) by providing perhydropolysilazane solution onto the surface of the matrix material, and
(d) exposing the perhydropolysilazane to vacuum ultraviolet light.

In another aspect, the present invention furthermore relates to method for preparing the optical device (200), wherein the method comprises following step (A);

(A) providing the optical medium (100) in an optical device.

In another aspect, the present invention relates to an optical medium (100) comprising at least a barrier layer (140) and a light luminescent part (130) including a nanosized fluorescent material (110) and a matrix material (120),

wherein the optical medium (100) is obtainable or obtained from the method for preparing the optical medium (100) comprising at least following steps (a) and (d) in this sequence;
(a) providing at least one nanosized fluorescent material (110), and a polysilazane as a matrix material (120) onto a substrate,
(b) applying steam process at a temperature in the range from 35° C. to 180° C.
(c) preparing a barrier layer (140) by providing perhydropolysilazane solution onto the surface of the matrix material, and
(d) exposing the perhydropolysilazane to vacuum ultraviolet light.

Further advantages of the present invention will become evident from the following detailed description.

### DESCRIPTION OF DRAWINGS

FIG. 1 shows a cross sectional view of a schematic of one embodiment of an optical medium.

FIG. 2 shows a cross sectional view of a schematic of one embodiment of an optical device of the invention.

FIG. 3 shows a cross sectional view of a schematic of another embodiment of an optical medium of the invention.

FIG. 4 shows a cross sectional view of a schematic of another embodiment of an optical medium of the invention.

FIG. 5 shows a cross sectional view of a schematic of another embodiment of an optical device of the invention.

FIG. 6 shows the measurement results of working example 3.

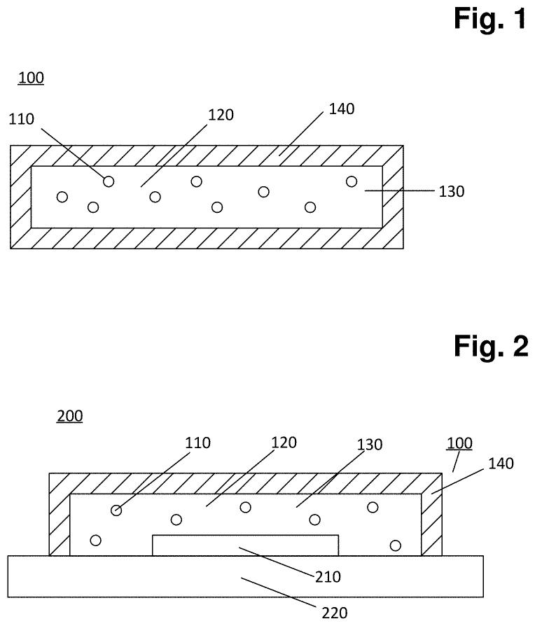

### LIST OF REFERENCE SIGNS IN FIG. 1

100. an optical medium
110. a nanosized fluorescent material
120. a matrix material
130. a light luminescent part
140. a barrier layer

### LIST OF REFERENCE SIGNS IN FIG. 2

200. an optical device
100. an optical medium
110. a nanosized fluorescent material
120. a matrix material
130. a light luminescent part
140. a barrier layer
210. a light source
220. a substrate

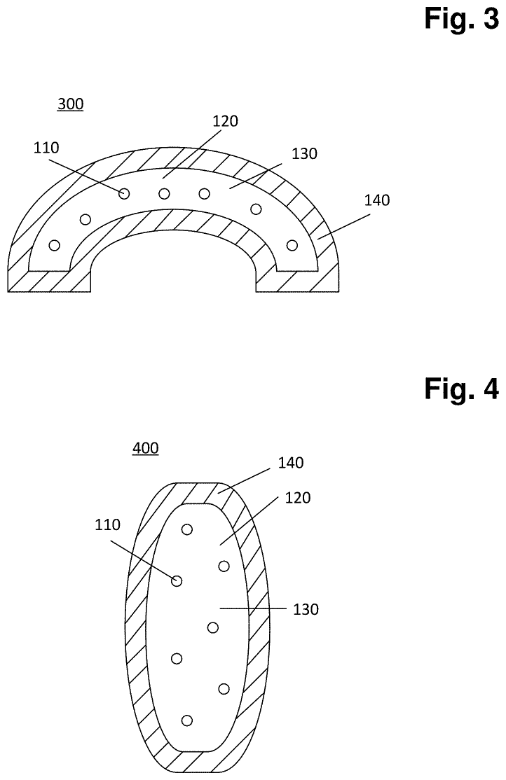

### LIST OF REFERENCE SIGNS IN FIG. 3

300. an optical medium
110. a nanosized fluorescent material
120. a matrix material
130. a light luminescent part
140. a barrier layer

### LIST OF REFERENCE SIGNS IN FIG. 4

400. an optical medium
110. a nanosized fluorescent material
120. a matrix material
130. a light luminescent part
140. a barrier layer

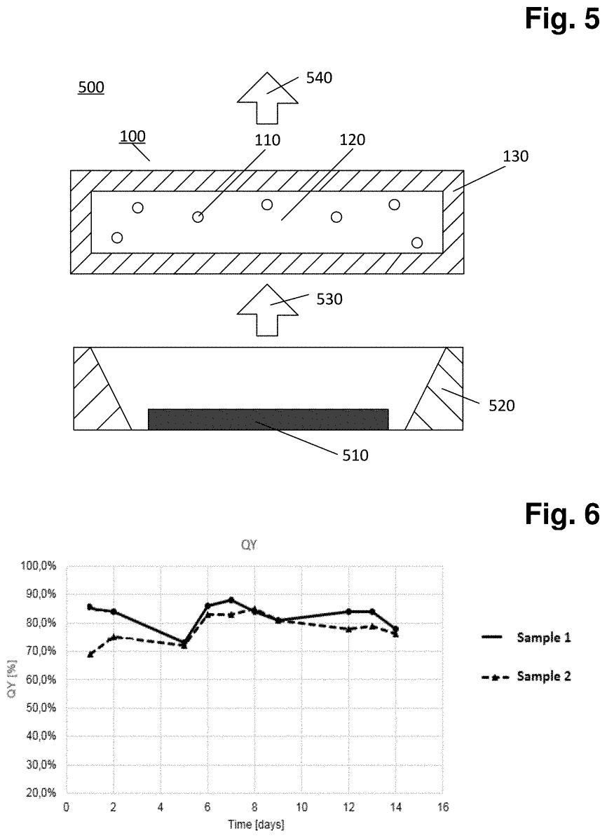

### LIST OF REFERENCE SIGNS IN FIG. 5

500. an optical device
100. an optical medium
110. a nanosized fluorescent material
120. a matrix material
130. a light luminescent part
140. a barrier layer
510. a light emitting diode element
520. a light reflector
530. light emission
540. converted light

### DETAILED DESCRIPTION OF THE INVENTION

According to the present invention, said optical medium (100) comprises, essentially consisting of, or consisting of at least a light luminescent part (130) and a barrier layer (140) placed over the light luminescent part (130), wherein the light luminescent part (130) comprises at least one nanosized fluorescent material (110), and a matrix material (120) comprising an organo-polysilazane.

Nanosized Fluorescent Materials

In a preferred embodiment of the present invention, the nanosized fluorescent material can be selected from the group consisting of nanosized inorganic phosphor materials, quantum sized materials such as quantum dots and or quantum rods, and a combination of any of these.

Without wishing to be bound by theory, it is believed that the nanosized fluorescent material can be used in a higher concentration ratio due to size effect and also may realize sharp vivid color(s) of the color conversion film. In some embodiments, the nanosized fluorescent material is a quantum sized material, such as a quantum dot material, quantum rod material or a combination of any of these.

According to the present invention, the term “nanosized” means the size in between 1 nm and 999 nm.

Thus, according to the present invention, the term “a nanosized fluorescent material” is taken to mean that the light emitting material which size of the overall diameter is in the range from 1 nm to 999 nm. And in case of the material has elongated shape, the length of the overall structures of the fluorescent material is in the range from 1 nm to 999 nm.

According to the present invention, the term “quantum sized” means the size of the semiconductor material itself without ligands or another surface modification, which can show the quantum confinement effect, like described in, for example, ISBN:978-3-662-44822-9.

In a preferred embodiment of the present invention, the light luminescent part (130) comprises comprises a plurality of nanosized fluorescent materials (110).

According to the present invention, a type of shape of the core of the nanosized light emitting material, and shape of the nanosized fluorescent material to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped nanosized light emitting materials can be used.

According to the present invention, the nanosized fluorescent material comprises a core/shell structure.

According to the present invention, the term “core/shell structure” means the structure having a core part and at least one shell part covering said core.

In some embodiments of the present invention, said core/shell structure can be core/one shell layer structure, core/double shells structure or core/multishells structure.

According to the present invention, the term “multishells” stands for the stacked shell layers consisting of three or more shell layers.

Each stacked shell layers of double shells and/or multishells can be made from same or different materials.

Generally, quantum sized light emitting material can emit sharp vivid colored light due to quantum size effect.

Therefore, in a preferred embodiment of the present invention, a nanosized fluorescent material is a quantum sized material comprising II-VI, III-V, or IV-VI semiconductors, or a combination of any of these.

For example, CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnPS/ZnS, InZnP/ZnSe/ZnS, ZnSe/CdS, ZnSe/ZnS or combination of any of these, can be used preferably.

In a preferred embodiment of the invention, the size of the overall structures of the quantum sized material, is from 1 nm to 100 nm, more preferably, it is from 1 nm to 30 nm, even more preferably, it is from 5 nm to 15 nm.

For examples as a quantum dot, CdSeS/ZnS alloyed quantum dots product number 753793, 753777, 753785, 753807, 753750, 753742, 753769, 753866, InP/ZnS quantum dots product number 776769, 776750, 776793, 776777, 776785, PbS core-type quantum dots product number 747017, 747025, 747076, 747084, or CdSe/ZnS alloyed quantum dots product number 754226, 748021, 694592, 694657, 694649, 694630, 694622 from Sigma-Aldrich, can be used preferably as desired.

For examples as a quantum rod, for red emission use, CdSe rods, CdSe dot in CdS rod, ZnSe dot in CdS rod, CdSe/ZnS rods, InP rods, CdSe/CdS rods, ZnSe/CdS rods or combination of any of these, for green emission use, such as CdSe rods, CdSe/ZnS rods, or combination of any of these, and for blue emission use, such as ZnSe, ZnS, ZnSe/ZnS core shell rods, or combination of any of these.

Examples of quantum rod materials have been described in, for example, the laid open international patent application No. WO2010/095140A.

In a preferred embodiment of the present invention, the surface of the nanosized fluorescent material can be over coated with one or more kinds of surface ligands.

Without wishing to be bound by theory it is believed that such a surface ligands may lead to disperse the nanosized fluorescent material in a solvent more easily.

The surface ligands in common use include phosphines and phosphine oxides such as Trioctylphosphine oxide (TOPO), Trioctylphosphine (TOP), and Tributylphosphine (TBP); phosphonic acids such as

Dodecylphosphonic acid (DDPA), Tridecylphosphonic acid (TDPA), Octadecylphosphonic acid (ODPA), and Hexylphosphonic acid (HPA); amines such as Dedecyl amine (DDA), Tetradecyl amine (TDA), Hexadecyl amine (HDA), and Octadecyl amine (ODA), thiols such as hexadecane thiol and hexane thiol; mercapto carboxylic acids such as mercapto propionic acid and mercaptoundecanoicacid; and a combination of any of these. And also. Polyethylenimine (PEI) also can be used preferably.

Examples of surface ligands have been described in, for example, the laid-open international patent application No. WO 2012/059931A.

Matrix Materials

As a matrix material according to the present invention, any type of publically known transparent matrix materials comprising an organo-polysilazane can be used.

According to the present invention, the term “organo-polzsilayane” means a polysilazane comprising at least one of organic substituent in a repeating unit of said polysilazane.

In a preferred embodiment of the present invention, the organo-polysilazane comprises at least a repeating unit represented by following chemical formula (I),

[—SiR¹R²—NR³-]ₓ (I)

wherein the formula, R¹, R², and R³ are at each occurrence, dependently or independently of each other, an alkyl group, an alkenyl group, a cycloalkyl group, an aryl group, an alkylsilyl group, an alkylamino group, an alkoxy group, or a combination of these; with the proviso that one or two of R₁, R₂, and R₃ can be hydrogen, and 0<x≤1.

In some embodiments, as said combination, an alkyl aryl group is suitable.

According to the present invention, said alkyl group, or said alkenyl group can be straight chain or branched chain, with preferably being of straight chain.

The term “aryl” denotes an aromatic carbon group or a group derived there from.

Aryl groups may be monocyclic or polycyclic, i.e. they may contain one ring (such as, for example, phenyl) or two or more rings, which may also be fused (such as, for example, naphthyl) or covalently bonded (such as, for example, biphenyl), or contain a combination of fused and bonded rings. Heteroaryl groups contain one or more heteroatoms, preferably selected from O, N, S and Se.

Particular preference is given to mono-, bi- or tricyclic aryl groups having 6 to 25 carbon atoms, which optionally contain fused rings and are optionally substituted. Preference is furthermore given to 5-, 6- or 7-membered aryl groups, in which, in addition, one or more CH groups may be replaced by N, S or O in such a way that 0 atoms and/or S atoms are not linked directly to one another.

Preferred aryl groups are, for example, phenyl, biphenyl, terphenyl, [1,1′:3′,1″]terphenyl-2′-yl, naphthyl, anthracene, binaphthyl, phenanthrene, pyrene, dihydropyrene, chrysene, perylene, tetracene, pentacene, benzo-pyrene, fluorene, indene, indenofluorene, and spirobifluorene.

More preferably, R₃ of the chemical formula (I) is a hydrogen atom.

In a preferred embodiment of the present invention, wherein the organo-polysilazane comprises at least repeating units of formulae (I) and (II),

[—SiR¹R²—NR³-]ₓ (I)

[—SiHR⁴—NR⁵]_{y} (II)

wherein the formula (I), R¹, R², and R³ are at each occurrence, dependently or independently of each other, an alkyl group, an alkenyl group, a cycloalkyl group, an aryl group, an alkylsilyl group, an alkylamino group, or an alkoxy group; in addition one or two of R₁, R₂, and R₃ can be hydrogen; wherein the formula (II) R⁴, and R⁵ are at each occurrence, dependently or independently of each other, an alkyl group, an alkenyl group, a cycloalkyl group, an aryl group, an alkylsilyl group, an alkylamino group, an alkoxy group, or a combination of these; with the proviso that one of R₄, and R₅ can be hydrogen, and 0<x+y≤1.

Furthermore preferably, the matrix material (120) comprises at least an organo-polysilazane selected from one or more members of the group consisting of organo-polysilazanes represented by following chemical formula (III) and organo-polysilazanes represented by following chemical formula (IV),

[SiR⁶R⁷—NH]ₐ—[SiHR⁸—NH]_{b} (III)

[Si R⁹R¹⁰—NH]_{c}—[SiHR¹¹—NH]_{d}—[SiR¹²R¹³NH]ₑ (IV)

wherein the formula (III), R⁶, R⁷, R⁸ are at each occurrence, dependently or independently of each other, an alkyl group having 1 to 15 carbon atoms, an alkenyl group having 2 to 10 carbon atoms, a cycloalkyl group having 3 to 10 carbon atoms, or an aryl group having 3 to 10 carbon atoms; the ratio of a and b is in the range from 1:3 to 3:1 and a+b=1; wherein the formula (IV) R⁹, R¹⁰, R¹¹ are at each occurrence, dependently or independently of each other, an alkyl group having 1 to 10 carbon atoms, an alkenyl group having 2 to 10 carbon atoms, a cycloalkyl group having 3 to 10 carbon atoms, or an aryl group having 3 to 10 carbon atoms; R¹² is an alkenyl group having 2 to 10 carbon atoms; R¹³ is an alkyl group having 1 to 10 carbon atoms, an alkenyl group having 2 to 10 carbon atoms, a cycloalkyl group having 3 to 10 carbon atoms, or an aryl group having 3 to 10 carbon atoms; and c+d+e=1.

In some embodiments of the present invention, the matrix material can further comprises a perhydropolysilazane.

The mixing ratio of perhydropolysilazane to organo-polysilazane is in the range from 0:100 to 90:10 by weight.

Preferably, it is in the range from 0:100 to 40:60 by weight.

More preferably, from 0:100 to 30:70 by weight.

Examples of organo-polysilazanes and perhydropolysilazanes are described in, for example, the laid open international patent application WO 2015/007778 A1, the laid open Japanese patent applications JP 2015-115369A, and JP 2014-77082A.

According to the present invention, the average molecular weight M_{w} of an organo-polysilazane and the average molecular weight M_{w} of a pherhydropolysilazane are not particularly limited.

Preferably, it is in the range from 1,000 to 20,000; with being more preferably in the range from 1,000 to 10,000.

According to the present invention, the average molecular weight M_{w} is determined by means of GPC (=gel permeation chromatography) against an internal polystyrene standard.

In some embodiments of the present invention, optionally, the matrix material (120) can further comprises one or more of transparent polymers.

In some embodiments, as the transparent polymer, publically known transparent polymers which is suitable for optical mediums such as optical devices can be used preferably to adjust the optical transparency of the matrix material (120) in a specified visible light wavelength, and the refractive index of the matrix material (120), and to control the oxygen absorption and/or moisture absorption of the matrix material (120) in a suitable range.

According to the present invention, in some embodiments, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

According to the present invention the term “polymer” means a material having a repeating unit and having the weight average molecular weight (Mw) 1000 or more.

In a preferred embodiment of the present invention, the weight average molecular weight (Mw) of the transparent polymer is in the range from 1,000 to 250,000.

More preferably it is from 5,000 to 200,000 with more preferably being from 10,000 to 150,000.

According to the present invention, the molecular weight M_{w} can be determined by means of GPC (=gel permeation chromatography) against an internal polystyrene standard.

In some embodiments, the transparent polymer can be preferably selected from one or more members of the group consisting of poly (meth)acrylates, polystyrene methyl (meth)acrylates, polystyrene, polyvinyl acetate, and polydivinylbenzene from the view point of better optical transparency, lower oxide absorption and high resistivity in high humidity condition.

Barrier Layer

According to the present invention, polysilazanes, especially, any perhydropolysilazane (hereafter “PHPS”) can be used preferably to fabricate a barrier layer (140).

Without wishing to be bound by theory, it is believed that perhzdropolzsilayanes may realize wet fabrication process instead of vapor deposition process and can reduce fabrication damage of nanosized fluorescent material in the process, and a barrier layer made from PHPS has less defects in the layer.

Thus, in one embodiment of the present invention, the barrier layer (140) is a layer obtained from perhydropolysilazane.

According to the present invention, in some embodiments, the barrier layer (140) comprises a gradient structure comprised of an outermost part and subsequent part in the layer, wherein the outermost part consists of silicon nitride.

In a preferred embodiment of the present invention, the gradient is a hydrogen content.

More preferably, the outermost part of the gradient structure to the matrix material (120) comprises higher amount of hydrogen than the opposite side of the gradient structure to the barrier layer (140).

Without wishing to be bound by theory, it is believed that the barrier layer fabricated by using PHPS solution may have lower refractive index than the refractive index of a barrier layer fabricated by any vapor deposition method (such as CVD), and may lead better refractive index matching to the matrix materials of the present invention.

In some embodiments of the present invention, the barrier layer (140) has the refractive index in the range from 1.38 to 1.85.

In a preferred embodiment of the present invention, the barrier layer (140) has the refractive index in the range from 1.45 to 1.60.

More preferably, the barrier layer (140) is fabricated from PHPS and has the refractive index in the range from 1.38 to 1.85; with being more preferably in the range from 1.45 to 1.60.

By changing the drying condition of the PHPS layer and by controlling vacuum ultraviolet (hereafter “VUV”) light irradiation condition, the refractive index value of the barrier layer (140) can be controlled.

According to the present invention, the term “vacuum ultraviolet” means an ultraviolet light having a peak wavelength in the range from 190 nm to 80 nm.

Polymerization Initiator Turning to the other components of the present invention, the matrix material and/or the PHPS layer of the present invention can optionally contain another one or more of additives if necessary. Such as a polymerization initiator.

Thus, in some embodiments of the invention, the matrix material further comprises a polymerization initiator.

Generally, there are two kinds of polymerization initiators which can be used in the present invention: one is a polymerization initiator generating an acid, base, or radical when exposed to radiation, and the other is a polymerization initiator generating an acid, base or radical when exposed to heat.

The polymerization initiator adoptable in the present is, for example, a photo acid-generator, which decomposes when exposed to radiation and releases an acid serving as an active substance for photo-curing the composition; a photo radical-generator, which releases a radical; a photo base-generator, which releases a base; a heat acid-generator, which decomposes when exposed to heat and releases an acid serving as an active substance for heat-curing the composition; a heat radical-generator, which releases a radical; and a heat base-generator, which releases a base. Examples of the radiation include visible light, UV rays, such as VUV rays, IR rays, X-rays, electron beams, α-rays and γ-rays.

In a preferred embodiment of the present invention, the amount of the polymerization initiator is in the range from 0.001 to 10 weight parts, more preferably 0.01 to 5 weight parts, based on 100 weight parts of the matrix material of the matrix layer or PHPS material of the barrier layer. More than 0.001 weight part is preferable to obtain the effect of the initiator. On the other hand, less than 10 weight parts of the polymerization initiator is preferable to prevent cracks of the fabricated color conversion sheet (100), or to prevent coloring of the fabricated sheet caused by decomposition of the initiator.

Examples of the above photo acid-generator include diazomethane compounds, diphenyliodonium salts, triphenylsulfonium salts, sulfonium salts, ammonium salts, phosphonium salts and sulfonamide compounds.

The structures of those photo acid-generators can be represented by the formula (A):

R⁺X⁻ (A).

Wherein the formula (A), R⁺ is hydrogen or an organic ion modified by carbon atoms or other hetero atoms provided that the organic ion is selected from the group consisting of alkyl groups, aryl groups, alkenyl groups, acyl groups and alkoxy groups. For example, R⁺ is diphenyliodonium ion or triphenylsulfonium ion.

Further, X⁻ is preferably a counter ion represented by any of the following formulas:

SbY₆⁻,

AsY₆⁻,

R^{a}ₚPY₆₋ₚ⁻,

R^{a}_{q}BY_{4-q}⁻,

R^{a}_{q}GaY_{4-q}⁻,

R^{a}SO₃⁻,

(R^{a}SO₂)₃C⁻,

(R^{a}SO₂)₂N⁻,

R^{a}COO⁻, and

SCN⁻
in which
Y is a halogen atom,
R^{a} is an alkyl group of 1 to 20 carbon atoms or an aryl group of 6 to 20 carbon atoms provided that each group is substituted with a substituent group selected from the group consisting of fluorine, nitro group and cyano group,
R^{b} is hydrogen or an alkyl group of 1 to 8 carbon atoms,
P is a number of 0 to 6, and
q is a number of 0 to 4.

Concrete examples of the counter ion (x⁻) include: BF₄⁻, (C₆F₅)₄B⁻, ((CF₃)₂C₆H₃)₄B⁻, PF₆⁻, (CF₃CF₂)₃PF₃⁻, SbF₆⁻, (C₆F₅)₄Ga⁻, ((CF₃)₂C₆H₃)₄Ga⁻, SCN⁻, (CF₃SO₂)₃C⁻, (CF₃SO₂)₂N⁻, formate ion, acetate ion, trifluoromethanesulfonate ion, nonafluorobutanesulfonate ion, methane-sulfonate ion, butanesulfonate ion, benzenesulfonate ion, p-toluenesulfonate ion, and sulfonate ion.

Among the photo acid-generators usable in the present invention, those generating sulfonic acids or boric acids are particularly preferred. Examples thereof include tricumyliodonium teterakis(pentafluoro phenyl)-borate (PHOTOINITIATOR2074 [trademark], manufactured by Rhodorsil), diphenyliodonium tetra (perfluoro phenyl)borate, and a compound having sulfonium ion and pentafluoroborate ion as the cation and anion moieties, respectively. Further, examples of the photo acid-generators also include triphenyl sulfonium trifluoromethanesulfonate, triphenylsulfonium camphor-sulfonate, triphenylsulfonium tetra(perfluoro-phenyl) borate, 4-acetoxyphenyldimethylsulfonium hexafluoro arsenate, 1-(4-n-butoxynaphthalene-1-yl) tetra hydro thiophenium trifluoromethanesulfonate, 1-(4,7-di butoxy-1-naphthalenyl)tetrahydro-thiophenium trifluoromethanesulfonate, diphenyliodonium trifluoro-methanesulfonate, and diphenyliodonium hexafluoro arsenate. Furthermore, it is still also possible to adopt photo acid-generators represented by the following formulas:

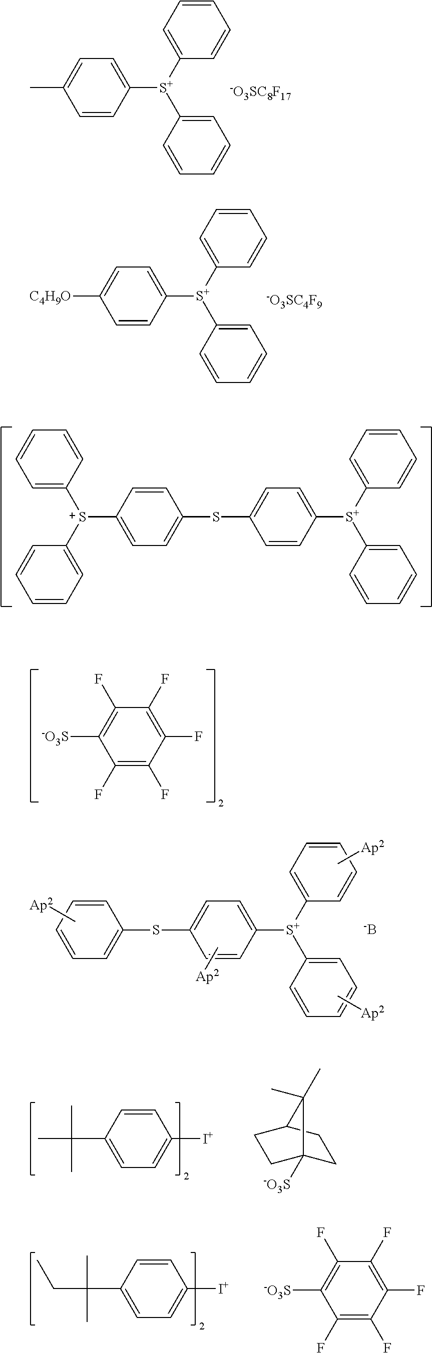

in which
each A is independently a substituent group selected from the group consisting of an alkyl group of 1 to 20 carbon atoms, an alkoxy group of 1 to 20 carbon atoms, an aryl group of 6 to 20 carbon atoms, an alkylcarbonyl group of 1 to 20 carbon atoms, an arylcarbonyl group of 6 to 20 carbon atoms, hydroxyl group, and amino group;
each p is independently an integer of 0 to 5; and
B⁻ is a fluorinated alkylsulfonate group, a fluorinated arylsulfonate group, a fluorinated alkylborate group, an alkylsulfonate group or an arylsulfonate group.

It is also possible to use photo acid-generators in which the cations and anions in the above formulas are exchanged each other or combined with various other cations and anions described above. For example, any one of the sulfonium ions represented by the above formulas can be combined with tetra(perfluorophenyl)borate ion, and also any one of the iodonium ions represented by the above formulas can be combined with tetra(per-fluorophenyl)borate ion. Those can be still also employed as the photo acid-generators.

The heat acid-generator is, for example, a salt or ester capable of generating an organic acid. Examples thereof include: various aliphatic sulfonic acids and salts thereof; various aliphatic carboxylic acids, such as, citric acid, acetic acid and maleic acid, and salts thereof; various aromatic carboxylic acids, such as, benzoic acid and phthalic acid, and salts thereof; aromatic sulfonic acids and ammonium salts thereof; various amine salts; aromatic diazonium salts; and phosphonic acid and salts thereof. Among the heat acid-generators usable in the present invention, salts of organic acids and organic bases are preferred, and further preferred are salts of sulfonic acids and organic bases.

Examples of the preferred heat acid-generators containing sulfonate ions include p-toluenesulfonates, benzenesulfonates, p-dodecylbenzenesulfonates, 1,4-naphthalenedisulfonates, and methanesulfonates.

Examples of the photo radical-generator include azo compounds, peroxides, acyl phosphine oxides, alkyl phenons, oxime esters, and titanocenes.

According to the present invention, as the photo radical-generator, acyl phosphine oxides, alkyl phenons, oxime esters, or a combination of any of these are more preferable. For examples, 2,2-dimethxye-1,2-diphenylethane-1-on, 1-hydroxy-cyclohexylphenylketone, 2-hydroxy-2-methyl-1-phenylpropan-1-on, 1-[4-(2-hydroxyethoxy)phenyl]-2-hydroxy-2-methyl-1-propane-1-on, 2-hydroxy-1-{4-[4-(2-hydroxy-2-methylpropionyl)benzyl]phenyl}-2-methylpropane-1-on, 2-methyl-1-(4-methylthiophenyl)-2-morpholinopropane-1-on, 2-benzyl-2-dimethylamino-1-(4-morpholinophenyl)-1-butanone, 2-(dimethylamino)-2-[(4-methylphenon)methyl]-1-[4-(4-morpholinyl)phenyl]-1-butanone, 2,4,6-trimethylbenzoyl-diphenylphosphine oxide, bis(2,4,6-trimethylbenzoyl)phenylphosphine oxide, 1,2-octanedione 1-[4-(phenylthio)-2-(o-benzoyl oxime)], ethanone 1-[9-ethyl-6-(2-methylbenzoyl)-9H-carbazole-3-yl]-1-(o-acetyl oxime) or a combination of any of these can be used preferably.

As the examples of the heat radical-generator, 2,2′ azobis(2-methylvaleronitrile), 2,2′-azobis(dimethylvaleronitrile) or a combination of any of these can be used preferably.

Examples of the photo base-generator include multi-substituted amide compounds having amide groups, lactams, imide compounds, and compounds having those structures.

Examples of the above heat base-generator include: imidazole derivatives, such as, N-(2-nitrobenzyloxycarbonyl)imidazole, N-(3-nitrobenzyloxy-carbonyl)imidazole, N-(4-nitrobenzyloxycarbonyl)imidazole, N-(5-methyl-2-nitrobenzyloxycarbonyl)imidazole, and N-(4-chloro-2-nitro-benzyloxycarbonyl)imidazole; 1,8-diazabicyclo(5,4,0)undecene-7, tertiary amines, quaternary ammonium salts, and mixture thereof. Those base-generators as well as the acid-generators and/or radical-generators can be used singly or in mixture.

Optical Medium (100)

In some embodiments of the present invention, the optical medium (100) can be an optical sheet, a filter or a lens. For example, a color filter, color conversion sheet, remote phosphor tape, another filter/sheet or a lens.

According to the present invention, the term “sheet” includes “layer” and “film” like structures.

In some embodiments of the present invention, the total thickness of the optical medium can be 5.0 μm or less from the view point of better out coupling effect of the optical medium (100). Preferably, it is in the range from 1.0 to 3.0 μm.

In some embodiments, the thickness of the barrier layer (140) can be in the range from 1 μm to 0.1 μm from the view point of better out coupling effect and better barrier property, and the thickness of the light luminescent part (130) can be in the range from 2 μm to 0.5 μm.

In case of the optical medium (100) is an optical lens, the total thickness of the optical medium (100) and the thickness of the barrier layer (140) and the light luminescentpart (130) can be any value as desired as a lens.

In some embodiments of the present invention, the optical medium (100) can further comprises a UV cut layer to reduce/prevent any UV damage of the nanosized fluorescent material (110).

Preferably, the UV cut layer is placed in between the barrier layer (140) and the light luminescent part (130) to protect the nanosized fluorescent material (110) from UV damage more effectively.

According to the present invention, any type of transparent UV cut layer can be used preferably.

Publically known transparent UV cut filters, films can also be used as a UV cut layer of the invention.

According to the present invention, the optical medium (100) can be a homogeneous or can comprise first and second sub color areas, in which at least first sub color area emits light having longer peak wavelength than the second sub color areas when it is illuminated by a light source.

In some embodiments of the present invention, the optical medium (100) can comprise red sub color areas, green sub color areas and blue sub color areas.

In some embodiments of the present invention, the optical medium (100) can mainly consist of red sub color areas, green sub color areas and blue sub color areas, if necessary.

In some embodiments of the present invention, optionally, the optical medium (100) can further comprises a black matrix (hereafter “BM”).

A material for the BM is not particularly limited. Well known materials, especially well known BM materials for color filters can be used preferably as desired. Such as black dye dispersed polymer composition, like described in JP 2008-260927A and WO 2013/031753A.

Fabrication method of the BM is not particularly limited, well known techniques can be used in this way. Such as, direct screen printing, photolithography, vapor deposition with mask.

Optical Device

In another aspect, the invention further relates to an optical device (200) comprising the optical medium (100).

In some embodiments of the present invention, the optical device (200) can be a liquid crystal display (LCD), Organic Light Emitting Diode (OLED), backlight unit for display, Light Emitting Diode (LED), Micro Electro Mechanical Systems (here in after “MEMS”), electro wetting display, or an electrophoretic display, a lighting device, and/or a solar cell.

In some embodiments of the present invention, the optical device (200) can include a transparent substrate (220).

In general, transparent substrate can be flexible, semi-rigid or rigid. Publically known transparent substrate suitable for optical devices can be used as desired.

Preferably, as a transparent substrate, a transparent polymer substrate, glass substrate, thin glass substrate stacked on a transparent polymer film, transparent metal oxides (for example, oxide silicone, oxide aluminum, oxide titanium), can be used.

A transparent polymer substrate can be made from polyethylene, ethylene-vinyl acetate copolymer, ethylene-vinyl alcohol copolymer, polypropylene, polystyrene, polymethyl methacrylate, polyvinylchloride, polyvinyl alcohol, polyvinylvutyral, nylon, polyether ether ketone, polysulfone, polyether sulfone, tetrafluoroethylene-erfluoroalkylvinyl ether copolymer, polyvinyl fluoride, tetraflyoroethylene ethylene copolymer, tetrafluoroethylene hexafluoro polymer copolymer, or a combination of any of these.

In some embodiments of the present invention, the optical device (200) can include a light source (210).

According to the present invention, the type of light source in the optical device is not particularly limited.

Such as a LED, cold cathode fluorescent lamp (hereafter CCFL), EL, OLED or a combination of any of these, can be used.

In some embodiments, the light source emits light having peak wavelength in a UV or a blue light region, such as UV or blue LEDs, CCFLs, ELs, OLEDs or a combination of any of these, can be used preferably.

In some embodiments of the present invention, optionally, the light source can be switchable.

In one embodiment of the present invention, optionally, the light source can further embrace a light guiding plate such as a light reflector (520) to increase light uniformity and/or to increase light-use efficiency from the light source.

In one embodiment of the present invention, the optical device (200) can further comprise a light modulator.

In a preferred embodiment of the present invention, the light modulator can be selected from the group consisting of liquid crystal element, Micro Electro Mechanical Systems (here in after “MEMS”), electro wetting element, and electrophoretic element.

In the case of the light modulator is a liquid crystal element, any type of liquid crystal element can be used in this way. For example, twisted nematic mode, vertical alignment mode, IPS mode, guest host mode liquid crystal element, which commonly used for LCDs are preferable.

Furthermore, according to the present invention, normally black TN mode liquid crystal element is also applicable as the light modulator.

In some embodiments of the present invention, the light modulator is placed on the light extraction side of the color conversion sheet (100).

In some embodiments of the present invention, the light modulator is placed in between the light source and the color conversion sheet (100).

According to the present invention, in some embodiments, the surface of the color conversion sheet (100), which opposite side from the light source, can have nano-meter scale structures instead of the sheet having nano-meter scale structures. Without wishing to be bound by theory, it is believed that the nano-meter scale structures may prevent light loss by the total reflection.

Thus, in one embodiment of the present invention, the optical device (200) further comprises a light source (210).

In one embodiment of the present invention, the optical device can be a light emitting diode device comprising the color conversion sheet (100), and a light emitting diode element (210).

In some embodiments of the present invention, optionally, the optical device (200) can further include a color filter layer. According to the present invention, as the color filter, any type of publically known color filter including red, green and blue sub color region for optical devices, such as LCD color filter, can be used in this way preferably.

Examples of optical devices have been described in, for example, WO 2010/095140 A2 and WO 2012/059931 A1.

Fabrication Methods

In another aspect, the present invention furthermore relates to method for preparing the optical medium (100), wherein the method comprises at least following steps (a) and (d) in this sequence;
(a) providing at least one nanosized fluorescent material (110), and an organo-polysilazane as a matrix material (120) onto a substrate,
(b) applying steam process at a temperature in the range from 35° C. to 180° C.
(c) preparing a barrier layer (140) by providing perhydropolysilazane solution onto the surface of the matrix material, and
(d) exposing the perhydropolysilazane to vacuum ultraviolet light.

In some embodiments, said steam process in step (b) is carried out at a temperature in the range from 50° C. to 150° C., with more preferably being of in the range from 70° C. to 120° C.

In some embodiments, the humidity in the steam process (b) is in the range from 50% rh to 100% rh, preferably.

More preferably, it is in the range from 65% rh to 99% rh. Even more preferably from 75% rh to 95% rh.

In some embodiments, said steam process is carried out in step (b) at a temperature in the range from 50° C. to 150° C. with the humidity in the range from 50% rh to 100% rh.

In some embodiments, the temperature in step (b) is in the range from 70° C. to 120° C. and the humidity in step (b) is 75% rh to 95% rh from the view point of better curing of the matrix material.

In a preferred embodiment of the present invention, the method further comprises step (e) after step (a) and before step (b);
(e) drying the organo-polysilazane.

Preferably, the method also comprises step (f) after step (c) and before step (d);
(f) drying the perhydropolysilazane.

In some embodiments of the present invention, the heat temperature of the drying step (e) and/or (f) can be in the range from 40° C. to 200° C. In a preferred embodiment of the present invention, the baking temperature in the drying step (e) and/or (f) is in the range from 70° C. to 180° C. More preferably, it is in the range from 80° C. to 160° C. Even more preferably, it is in the range from 100° C. to 140° C.

The drying time is not particularly restricted, preferably it is from 30 seconds to 24 hours, more preferably from 60 seconds to 10 hours.

In some embodiments, all process can be done under an inert condition such as in nitrogen atmosphere.

Coating Step

According to the present invention, to provide at least one nanosized fluorescent material (110), and a matrix material (120) onto a substrate, and/or providing perhydropolysilazane solution onto the surface of the luminescent part (130), any type of publically known coating method can be used preferably. For examples, inkjet printing, immersion coating, gravure coating, roll coating, bar coating, brush coating, spray coating, doctor coating, flow coating, spin coating, and slit coating.

The substrate to be coated with providing perhydropolysilazane solution onto the surface of the matrix material in step (a) is also not particularly limited, and can be properly selected from, for example, a silicon substrate, a glass substrate, or a polymer film.

Solvents

According to the present invention, a wide variety of publically known solvents can be used preferably in fabrication. There are no particular restrictions on the solvent as long as it can homogeneously dissolve or disperse the above a matrix material or polysilazanes for a barrier layer, the polymerization initiator, and additives incorporated optionally.

In a preferred embodiment of the present invention, the solvent can be selected from the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; aromatic hydrocarbons, such as, benzene, toluene and xylene; ketones, such as, methyl ethyl ketone, acetone, methyl amyl ketone, methyl isobutyl ketone, and cyclohexanone; alcohols, such as, ethanol, propanol, butanol, hexanol, cyclohexanol, ethylene glycol, and glycerin; esters, such as, ethyl 3-ethoxypropionate, methyl 3-methoxypropionate and ethyl lactate; and cyclic asters, such as, γ-butyrolactone; heptane; dibutylether; or purified water. Those solvents are used singly or in combination of two or more, and the amount thereof depends on the coating method and the thickness of the coating.

The amount of the solvent in the photosensitive composition can be freely controlled according to the method of coating the composition. For example, if the composition is to be spray-coated, it can contain the solvent in an amount of 90 wt. % or more. Further, if a slit-coating method, which is often adopted in coating a large substrate, is more to be carried out, the content of the solvent is preferably 60 wt. % or more, preferably 70 wt. % or more.

Exposing Step as Step (d) to Cure the Perhydropolysilazane

In a preferable embodiment of the present invention, after the coating of the perhydropolysilazane is formed, the surface thereof can be exposed to vacuum ultraviolet (hereafter “VUV”) light having peak wavelength at 172 nm or at 185 nm. As a light source for the exposure, it is possible to use any publically known VUV light source. Energy of the exposure light depends on the light source and the thickness of the coating, but is generally 10 to 2000 mJ/cm², preferably 20 to 1000 mJ/cm² to obtain the barrier layer obtained from PHPS.

According to the present invention, preferably, the barrier layer is SiN. Thus, preferably, all process can be carried out under an inert gas atmosphere. More preferably, all process can be carried out under purified nitrogen atmosphere to minimize oxygen density in the fabrication atmosphere.

In a preferred embodiment of the present invention, all fabrication process except for VUV light irradiation process as step (c) can be carried out under yellow light condition.

In another aspect, the present invention furthermore relates to method for preparing the optical device (200), wherein the method comprises following step (A);

(A) providing the optical medium (100) in an optical device.

In another aspect, the present invention also relates to an optical medium (100) comprising a barrier layer (140) and a light luminescent part (130) including a nanosized fluorescent material (110) and a matrix material (120),

wherein the optical medium (100) is obtainable or obtained from the method comprises at least following steps (a) and (d) in this sequence;
(a) providing at least one nanosized fluorescent material (110), and an organo polysilazane as a matrix material (120) onto a substrate,
(b) applying steam process at a temperature in the range from 35° C. to 180° C.
(c) preparing a barrier layer (140) by providing perhydropolysilazane solution onto the surface of the matrix material, and
(d) exposing the perhydropolysilazane to vacuum ultraviolet light.

More details of said method are described in the section of “Fabrication methods”.

The invention is described in more detail in reference to the following examples, which are only illustrative and do not limit the scope of the invention.

### EXAMPLES

### Example 1

FIG. 1 discloses one example of an optical medium (100) of the present invention including at least one nanosized fluorescent material (110) (for example, red and/or green), a matrix material (120), and a barrier layer (130).

### Example 2

FIG. 2 shows one example of an optical device (200) of the present invention, including an optical medium (100), at least one nanosized fluorescent material (110) (for example, red and/or green), a matrix material (120), a barrier layer (130), and light emitting diode element (210). A substrate (220) is an optional.

### Example 3

FIG. 3 shows another example of an optical medium (100) of the present invention.

### Example 4

FIG. 4 shows another example of an optical medium (100) of the present invention. In this example, the optical medium (100) has lens like shape to control optical pass, direction and strength of an incident light. Instead of double-convex lens shape, a plano-convex lens, a convex lens, or a concave lens shapes can be used, if it is desired.

### Example 5

FIG. 5 shows another example of an optical device of the present invention. In this example, the optical medium (100) is used as light conversion layer of the LED chip. Instead of the light emitting diode element (510), a sensor chip can be used to detect converted color light from the optical medium (100), if it is desired.

Each feature disclosed in this specification, unless stated otherwise, may be replaced by alternative features serving the same, equivalent, or similar purpose. Thus, unless stated otherwise, each feature disclosed is but one example of a generic series of equivalent or similar features.

### Effect of the Invention

The present invention provides,

1. a novel optical medium comprising a nanosized fluorescent material such as quantum sized materials, and a matrix material, which can show improved initial absolute quantum yield,
2. a novel optical medium comprising a nanosized fluorescent material, and a matrix material, which can keep good absolute quantum yield, especially in a thermal stress environment,
3. a novel optical medium comprising a nanosized fluorescent material, and a matrix material which can show improved absolute quantum yield in a high humidity environment,
4. a novel optical medium comprising a nanosized fluorescent material and a matrix material, which can show improved light stress resistivity under light illumination condition,
5. a novel optical medium comprising a nanosized fluorescent material such as quantum sized materials, and a matrix material, which can fit to wet fabrication process well.

### Definition of Terms

The term “fluorescent” is defined as the physical process of light emission by a substance that has absorbed light or other electromagnetic radiation. It is a form of luminescence. In most cases, the emitted light has a longer wavelength, and therefore lower energy, than the absorbed radiation.

The term “semiconductor” means a material which has electrical conductivity to a degree between that of a conductor (such as copper) and that of an insulator (such as glass) at room temperature.

The term “inorganic” means any material not containing carbon atoms or any compound that containing carbon atoms ionically bound to other atoms such as carbon monoxide, carbon dioxide, carbonates, cyanides, cyanates, carbides, and thiocyanates.

The term “emission” means the emission of electromagnetic waves by electron transitions in atoms and molecules.

The term “photosensitive” means that the respective composition chemically reacts in response to suitable light irradiation. The light is usually chosen from visible or UV light. The photosensitive response includes hardening or softening of the composition, preferably hardening. Preferably the photosensitive composition is a photo-polymerizable composition.

The working examples 1-3 below provide descriptions of the present invention, as well as an in detail description of their fabrication.

### Working Examples

### Working Example 1: Fabrication of an Optical Medium (100)-Organo-Polysilazane+Q-Rod/PHPS

A 3*3 cm glass substrate is cleaned by a tissue containing isopropanol and then the glass substrate is further cleaned by spin coating for 30 second at 1000 rpm with isopropanol.

1 g of organo-polysilazane solution (25 wt. % of the organo-polysilazane in toluene) including 1 wt. % of radical-generator Luperox® 531M80 is mixed with 1 g of quantum sized material solution (3 wt. % of the quantum sized materials in toluene). The organo-polysilazane has the repeating unit represented by the chemical formula of [Si(CH₃)₂—NH]— [SiH(CH₃)—NH].

Then the obtained solution is spin coated onto the cleaned glass substrate at 1,000 rpm for 30 seconds. And then it is dried at 130° C. for 5 minutes, then it is put into a climate chamber and cured at 85° C./85% rh for 16 hours.

Then it is cleaned again with isopropanol by spincoating at 2500 rpm for 30 seconds.

Afterwards, perhydropolysilazane (hereafter “PHPS”) solution (20 wt. % of PHPS in Dibutylether; from Merck) is printed onto the cured organo polysilazane of the substrate by syringe with 0.2 μm filter until the grass substrate is completely flooded. Then it is spin coated at 2500 rpm for 30 seconds, and dried at 130° C. for 5 minutes.

After PHPS drying process, the PHPS layer is exposed to vacuum ultraviolet (hereafter “VUV”) light having peak wavelength 172 nm at 25 mW/cm² for 30 minutes with the VUV device (from IOT) under nitrogen atmosphere to accelerate Nitriding reaction of PHPS layer.

Then, the sample 1 having around 0.3 um barrier layer coated on organo polysilazane/Q-rod layer is finally obtained.

All process are carried out under nitrogen atmosphere. And except for VUV light irradiation, all process are carried out under filtered yellow light condition.

### Working Example 2: Fabrication of an Optical Medium (100)-Organo-Polysilazane+Q-Rod+PHPS/PHPS

The sample 2 is fabricated in the same manner as described in working example 1 except for 0.2 g of PHPS solution (20 wt. % of PHPS in Dibutylether) is added into 1 g of organo-polysilazane solution (25 wt. % of the organo-polysilazane in toluene) including 1 wt. % of Luperox® 531M80.

### Working Example 3: QY Evaluation

First, the sample 1 and 2 are put in a climate chamber with the condition of 85° C./85% rh, and it is kept in that thermal stress, very high humidity environment (85° C./85% rh) and light illumination stress environment with the condition of 15 mW/cm² at 450 nm for 14 days.

The absolute photo luminescent quantum yield (hereafter “QY”) of the sample 1 and 2 is each independently measured by Quantaurus-QY

Absolute PL quantum yields measurement system C11347-11 (Hamamatsu).

FIG. 6 shows the results of the measurement.

As shown in FIG. 6, the sample 1 and 2 show very good initial quantum yield, and improved resistivity in the thermal stress, very high humidity and light stress environment (85° C./85% rh under 15 mW/cm² at 450 nm LED light illumination condition). After 14 days of the stress test, the samples still keep very high quantum yield.

1. An optical medium (100) comprising at least a light luminescent part (130) and a barrier layer (140) placed over the light luminescent part (130), wherein the light luminescent part (130) comprises at least one nanosized fluorescent material (110), and a matrix material (120) comprising an organo-polysilazane.

2. The optical medium (100) according to claim 1, wherein the organo-polysilazane comprises at least a repeating unit represented by following chemical formula (I),
[—SiR¹R²—NR³—]ₓ (I)
wherein the formula, R¹, R², and R³ are at each occurrence, dependently or independently of each other, an alkyl group, an alkenyl group, a cycloalkyl group, an aryl group, an alkylsilyl group, an alkylamino group, an alkoxy group, or a combination of these; with the proviso that one or two of R₁, R₂, and R₃ can be hydrogen, and 0<x≤1.

3. The optical medium (100) according to claim 1, wherein R₃ of the chemical formula (I) is a hydrogen atom.

4. The optical medium (100) according to claim 1, wherein the organo-polysilazane comprises repeating units of formulae (I) and (II),
[—SiR¹R²—NR³—]ₓ (I)
[—SiHR⁴—NR⁵—]_{y} (II)
wherein the formula (I), R¹, R², and R³ are at each occurrence, dependently or independently of each other, an alkyl group, an alkenyl group, a cycloalkyl group, an aryl group, an alkylsilyl group, an alkylamino group, or an alkoxy group; in addition one or two of R₁, R₂, and R₃ can be hydrogen; wherein the formula (II) R⁴, and R⁵ are at each occurrence, dependently or independently of each other, an alkyl group, an alkenyl group, a cycloalkyl group, an aryl group, an alkylsilyl group, an alkylamino group, an alkoxy group, or a combination of these; with the proviso that one of R₄, and R₅ can be hydrogen, and 0<x+y≤1.

5. The optical medium (100) according to claim 1, wherein the matrix material (120) comprises at least an organo-polysilazane selected from one or more members of the group consisting of organo-polysilazanes represented by following chemical formula (III) and organo-polysilazanes represented by following chemical formula (IV),
[SiR⁶R⁷—NH]ₐ—[SiHR⁸—NH]_{b} (III)
[Si R⁹R¹⁰—NH]_{c}—[SiHR¹¹—NH]_{d}—[SiR¹²R¹³NH]ₑ (IV)
wherein the formula (III), R⁶, R⁷, R⁸ are at each occurrence, dependently or independently of each other, an alkyl group having 1 to 15 carbon atoms, an alkenyl group having 2 to 10 carbon atoms, a cycloalkyl group having 3 to 10 carbon atoms, or an aryl group having 3 to 10 carbon atoms; the ratio of a and b is in the range from 1:3 to 3:1 and a+b=1; wherein the formula (IV) R⁹, R¹⁰, R¹¹ are at each occurrence, dependently or independently of each other, an alkyl group having 1 to 10 carbon atoms, an alkenyl group having 2 to 10 carbon atoms, a cycloalkyl group having 3 to 10 carbon atoms, or an aryl group having 3 to 10 carbon atoms; R¹² is an alkenyl group having 2 to 10 carbon atoms; R¹³ is an alkyl group having 1 to 10 carbon atoms, an alkenyl group having 2 to 10 carbon atoms, a cycloalkyl group having 3 to 10 carbon atoms, or an aryl group having 3 to 10 carbon atoms; and c+d+e=1.

6. The optical medium (100) according to claim 1, wherein the matrix material (120) further comprises perhydropolysilazane.

7. The optical medium (100) according to claim 1, wherein the barrier layer (140) comprises N and Si atoms.

8. The optical medium (100) according to claim 1, wherein the barrier layer (140) is a layer obtained from perhydropolysilazane.

9. The optical medium (100) according to claim 1, wherein the barrier layer (140) comprises a gradient structure comprised of an outermost part and subsequent part in the layer, wherein the outermost part consists of silicon nitride.

10. The optical medium (100) according to claim 1, wherein the gradient is a hydrogen content.

11. The optical medium (100) according to claim 1, wherein the outermost part of the gradient structure to the matrix material (120) comprises higher amount of hydrogen than the opposite side of the gradient structure to the barrier layer (140).

12. The optical medium (100) according to claim 1, wherein the barrier layer (140) has the refractive index in the range from 1.38 to 1.85.

13. The optical medium (100) according to claim 1, wherein the barrier layer (130) has the refractive index in the range from 1.45 to 1.60.

14. The optical medium (100) according to claim 1, wherein the optical medium (100) further comprises an UV cut layer in between the matrix material (120) and the barrier layer (140).

15. A method which comprises including the optical medium (100) according to claim 1, in an optical device.

16. An optical device (200) comprising the optical medium (100) according to claim 1.

17. The optical device (200) according to claim 16, wherein the optical device further comprises a light source (210).

18. Method for preparing the optical medium (100) wherein the method comprises at least following steps (a) and (d) in this sequence;
(a) providing at least one nanosized fluorescent material (110), and an organo polysilazane as a matrix material (120) onto a substrate,
(b) applying steam process at a temperature in the range from 35° C. to 180° C.
(c) preparing a barrier layer (140) by providing perhydropolysilazane solution onto the surface of the matrix material, and
(d) exposing the perhydropolysilazane to vacuum ultraviolet light.

19. Method for preparing the optical device (200), wherein the method comprises following step (A);
(A) providing the optical medium (100) according to claim 1, in an optical device.

20. An optical medium (100) comprising at least a barrier layer (140) and a light luminescent part (130) including a nanosized fluorescent material (110) and a matrix material (120),
wherein the optical medium (100) is obtainable or obtained from the method according to claim 18.
